(19) United States
(12) Patent Application Publication
(10) Pub. No.: US 2026/0215350 A1
(43) Pub. Date: Jul. 23, 2026

(54) STACKED STRUCTURE AND SEMICONDUCTOR DEVICE

(71) Applicant: SONY GROUP CORPORATION, TOKYO (JP)

(72) Inventor: NAOKI HIRAO, TOKYO (JP)

(21) Appl. No.: 19/157,944

(22) PCT Filed: Feb. 13, 2024
(86) PCT No.: PCT/JP2024/004786

§ 371 Date: Aug. 19, 2025

(30) Foreign Application Priority Data
Mar. 13, 2023 (JP) 2023-038822

(51) Int. Cl. H10W 90/00; H10W 72/90

(52) U.S. Cl. CPC H10W 90/792; H10W 72/932; H10W 72/9445

(57) ABSTRACT

A stacked structure according to one embodiment of the present disclosure includes: a first substrate including a first surface and a second surface that are opposed to each other, the first substrate including a first array in which a plurality of first bonding sections is provided at the second surface in a row direction and a column direction in an array manner; and a second substrate including a third surface opposed to the second surface and a fourth surface disposed on an opposite side from the third surface, the second substrate including a second array in which a plurality of second bonding sections is provided at the third surface in the row direction and the column direction in an array manner, the plurality of second bonding sections being correspondingly bonded to the plurality of first bonding sections. The plurality of first bonding sections, the plurality of second bonding sections, or both of the plurality of first bonding sections and the plurality of second bonding sections each have a plane shape having a longitudinal direction and a transverse direction that intersect each other, and of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.

### TECHNICAL FIELD

The present disclosure relates to a stacked structure and a semiconductor device each obtained through hybrid bonding.

### BACKGROUND ART

For example, Patent Literature 1 discloses a semiconductor device including a first semiconductor substrate and a second semiconductor substrate that are stacked to each other. At the bonding surfaces of these substrates, copper wirings are opposed to each other. These copper wirings are bonded so as to be orthogonal to each other in the longitudinal direction (orthogonal bonding), or are bonded so as to be parallel to each other in the longitudinal direction (parallel bonding).

### CITATION LIST

### Patent Literature

Patent Literature 1: WO 2020/044943

### SUMMARY OF THE INVENTION

Incidentally, in a case of a stacked structure in which plural substrates are stacked to each other, fine bonding is demanded.

It is desired to provide a stacked structure and a semiconductor device that make it possible to perform fine bonding.

A stacked structure according to one embodiment of the present disclosure includes: a first substrate including a first surface and a second surface that are opposed to each other, the first substrate including a first array in which a plurality of first bonding sections is provided at the second surface in a row direction and a column direction in an array manner; and a second substrate including a third surface opposed to the second surface and a fourth surface disposed on an opposite side from the third surface, the second substrate including a second array in which a plurality of second bonding sections is provided at the third surface in the row direction and the column direction in an array manner, the plurality of second bonding sections being correspondingly bonded to the plurality of first bonding sections, in which the plurality of first bonding sections, the plurality of second bonding sections, or both of the plurality of first bonding sections and the plurality of second bonding sections each have a plane shape having a longitudinal direction and a transverse direction that intersect each other, and of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.

A semiconductor device according to one embodiment of the present disclosure includes: a first substrate including a first surface and a second surface that are opposed to each other, the first substrate including a plurality of first semiconductor elements and a first array in which a plurality of first bonding sections provided at the second surface is provided in a row direction and a column direction in an array manner, the plurality of first bonding sections being correspondingly electrically coupled to the plurality of first semiconductor elements; and a second substrate including a third surface opposed to the second surface and a fourth surface disposed on an opposite side from the third surface, the second substrate including a plurality of drive circuits and a second array in which a plurality of second bonding sections provided at the third surface is provided in the row direction and the column direction in an array manner, the plurality of drive circuits controlling drive of the plurality of first semiconductor elements, the plurality of second bonding sections being correspondingly electrically coupled to the plurality of drive circuits, in which the plurality of first bonding sections, the plurality of second bonding sections, or both of the plurality of first bonding sections and the plurality of second bonding sections each have a plane shape having a longitudinal direction and a transverse direction that intersect each other, and of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.

In the stacked structure according to one embodiment of the present disclosure and the semiconductor device according to one embodiment, the plurality of first bonding sections and the plurality of second bonding sections are provided in the row and column directions in the array manner at corresponding bonding surfaces (the second surface and the third surface) of the first substrate and the second substrate that are bonded together. Furthermore, the plurality of first bonding sections, the plurality of second bonding sections, or both of them that constitute the first array and the second array each have a plane shape having the longitudinal direction and the transverse direction that intersect each other. In addition, of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction. This makes it possible to improve the bonding margin between the first bonding section and the second bonding section.

### BRIEF DESCRIPTION OF THE DRAWINGS

FIG. 1 is a sectional schematic view of one example of the schematic configuration of a stacked structure according to one embodiment of the present disclosure.

FIG. 2 is a schematic plan view of one example of a layout of pad sections at a bonding surface of the stacked structure illustrated in FIG. 1.

FIG. 3 is a schematic plan view of one example of a layout of pad sections at a first substrate side (A) and a second substrate side (B) of the stacked structure illustrated in FIG. 1.

FIG. 4 is a sectional schematic view of one example of the configuration of a semiconductor device (light emission device) according to one embodiment of the present disclosure.

FIG. 5 is a schematic view of one example of a planar configuration of the entire light emission device illustrated in FIG. 4.

FIG. 6 is a schematic view in which the planar configuration of the light emission device illustrated in FIG. 5 is partially enlarged.

FIG. 7A is a schematic plan view of one example of a layout of pad sections at a bonding surface of a typical stacked structure according to a comparative example.

FIG. 7B is a diagram used to describe the misalignment of bonding in the stacked structure illustrated in FIG. 7A.

FIG. 8A is a schematic plan view of another example of a layout of pad sections at a bonding surface of a typical stacked structure according to a comparative example.

FIG. 8B is a diagram used to describe the misalignment of bonding in the stacked structure illustrated in FIG. 8A.

FIG. 9 is a schematic plan view used to describe a layout and the misalignment of bonding of pad sections at the bonding surface of a stacked structure according to a comparative example.

FIG. 10A is a diagram used to describe a bonding margin for misalignment of bonding in the layout of pad sections illustrated in FIG. 2.

FIG. 10B is a schematic plan view of one example of the misalignment of bonding in the layout of pad sections illustrated in FIG. 2.

FIG. 10C is a schematic plan view of another example of the misalignment of bonding in the layout of pad sections illustrated in FIG. 2.

FIG. 11 is a schematic plan view of one example of a layout of pad sections according to a first modification example of the present disclosure.

FIG. 12 is a schematic plan view of another example of a layout of pad sections according to the first modification example of the present disclosure.

FIG. 13 is a schematic plan view of another example of a layout of pad sections according to the first modification example of the present disclosure.

FIG. 14 is a schematic plan view of another example of a layout of pad sections according to the first modification example of the present disclosure.

FIG. 15 is a schematic plan view of another example of a layout of pad sections according to the first modification example of the present disclosure.

FIG. 16 is a diagram illustrating one example of the plane shape of a pad section according to a second modification example of the present disclosure.

FIG. 17 is a diagram illustrating another example of the plane shape of a pad section according to the second modification example of the present disclosure.

FIG. 18 is a diagram illustrating another example of the plane shape of a pad section according to the second modification example of the present disclosure.

FIG. 19 is a diagram illustrating another example of the plane shape of a pad section according to the second modification example of the present disclosure.

FIG. 20 is a diagram illustrating another example of the plane shape of a pad section according to the second modification example of the present disclosure.

FIG. 21 is a diagram illustrating another example of the plane shape of a pad section according to the second modification example of the present disclosure.

FIG. 22 is a diagram used to describe one example of a layout of pad sections at a bonding surface according to a third modification example of the present disclosure.

FIG. 23 is a schematic plan view of one example of a layout of a pad section in the region A illustrated in FIG. 22.

FIG. 24 is a schematic plan view of one example of a layout of a pad section at positions B1, B2, B3, and B4 illustrated in FIG. 22.

FIG. 25 is a schematic plan view of one example of the arrangement of pad sections from the position B1 to the position B2 illustrated in FIG. 22.

FIG. 26 is a schematic plan view of another example of the arrangement of pad sections from the position B1 to the position B2 illustrated in FIG. 22.

FIG. 27 is a diagram illustrating one example of a relationship between a display region and an arrangement region for a plurality of pad sections at a bonding surface in a light emission device according to a fourth modification example of the present disclosure.

FIG. 28 is a diagram illustrating another example of a relationship between a display region and an arrangement region for a plurality of pad sections at the bonding surface in the light emission device according to the fourth modification example of the present disclosure.

FIG. 29 is a diagram illustrating another example of a relationship between a display region and an arrangement region for a plurality of pad sections at the bonding surface in the light emission device according to the fourth modification example of the present disclosure.

FIG. 30 is a schematic plan view of one example of the schematic configuration of a stacked structure according to a fifth modification example of the present disclosure.

FIG. 31 is a sectional schematic view of one example of the schematic configuration of a stacked structure according to a sixth modification example of the present disclosure.

FIG. 32 is a sectional schematic view of one example of the configuration of a semiconductor device (light emission device) to which the configuration illustrated in FIG. 31 is applied.

FIG. 33 is a perspective view of one example of the configuration of an image display device according to an application example of the present disclosure.

FIG. 34 is a schematic view of one example of a layout of wirings in the image display device illustrated in FIG. 33.

FIG. 35 is a perspective view of one example of the configuration of an image display device according to an application example of the present disclosure.

FIG. 36 is a perspective view of the configuration of a package substrate illustrated in FIG. 35.

FIG. 37 is a perspective view of the configuration of a unit substrate illustrated in FIG. 36.

FIG. 38 is a diagram illustrating an example of an image display device according to an application example of the present disclosure.

### MODES FOR CARRYING OUT THE INVENTION

Below, one embodiment according to the present disclosure will be described in detail with reference to the drawings. The description below is given as one specific example of the present disclosure, and the present disclosure should not be limited to the following modes. In addition, as for the arrangement, the dimension, the dimensional ratio, or the like of each constituent element described in each of the drawings, the present disclosure is not limited to them. Note that, the description will be given in the following order.
1. Embodiment
(Example of a stacked structure in which: a longitudinal direction and a transverse direction are provided; a plurality of bonding sections is formed in row and column directions in an array manner; the longitudinal direction of the plurality of bonding sections has a predetermined angle relative to a row direction or a column direction; and a pair of adjacent bonding sections is substantially in mirror-image symmetry)
   1-1. Configuration of Stacked Structure
   1-2. Configuration of Semiconductor Device
   1-3. Workings and Effects
2. Modification Example
   2-1. First Modification Example (another example of a layout of pad sections)
   2-2. Second Modification Example (another example of a shape of pad section)
   2-3. Third Modification Example (another example of a layout of pad sections)
   2-4. Fourth Modification Example (another example of a relationship of array of semiconductor elements and array of pad sections in a substrate)
   2-5. Fifth Modification Example (another example of a stacked structure)
   2-6. Sixth Modification Example (another example of a stacked structure)
3. Application Example

### 1. Embodiment

### 1-1. Configuration of Stacked Structure

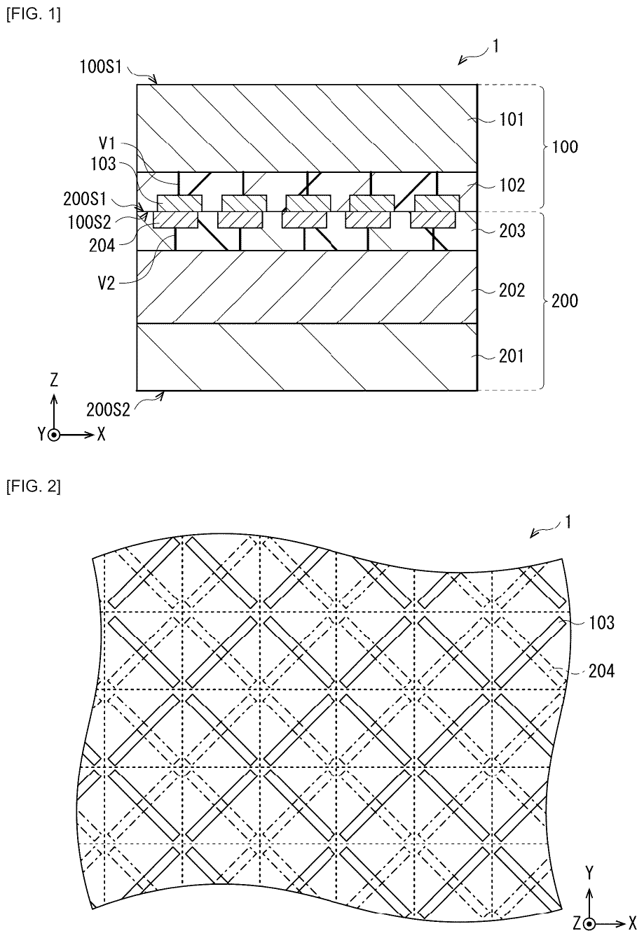

FIG. 1 is a sectional schematic view of one example of the schematic configuration of a stacked structure (stacked structure 1) according to one embodiment of the present disclosure.

The stacked structure 1 includes a first substrate 100 including a surface 100S1 and a surface 100S2 that are opposed to each other, and also includes a second substrate 200 including a surface 200S1 and a surface 200S2 that are opposed to each other. The first substrate 100 and the second substrate 200 are stacked to each other with the surface 100S2 and the surface 200S1 serving as bonding surfaces. This first substrate 100 corresponds to one specific example of a “first substrate” in the embodiment according to the present disclosure. The surface 100S1 corresponds to one specific example of a “first surface” in the embodiment according to the present disclosure. The surface 100S2 corresponds to one specific example of a “second surface” in the embodiment according to the present disclosure. The second substrate 200 corresponds to one specific example of a “second substrate” in the embodiment according to the present disclosure. The surface 200S1 corresponds to one specific example of a “third surface” in the embodiment according to the present disclosure. The surface 200S2 corresponds to one specific example of a “fourth surface” in the embodiment according to the present disclosure.

The first substrate 100 includes a semiconductor layer 101 and a coupling layer 102, for example. Although illustration is not given, the semiconductor layer 101 includes, for example, a plurality of semiconductor elements formed, for example, in row and column directions in an array manner, for example, at pitches of not more than 10 μm. The coupling layer 102 constitutes a surface (surface 100S2) bonded to the second substrate 200. A plurality of pad sections 103 is formed at the surface 100S2 of the coupling layer 102, for example, in row and column directions in an array manner. The plurality of pad sections 103 corresponds to one specific example of a “plurality of first bonding sections” in the embodiment according to the present disclosure. The plurality of pad sections 103 is correspondingly electrically coupled, through a via V1, to a plurality of semiconductor elements formed in the semiconductor layer 101.

For example, the second substrate 200 has a coefficient of linear expansion differing from that of the first substrate 100. In the second substrate 200, a support substrate 201, a circuit layer 202, and a coupling layer 203 are stacked in this order, for example. The circuit layer 202 includes a plurality of circuits, for example, in row and column directions in an array manner, for example. The coupling layer 203 constitutes a surface (surface 200S1) bonded to the first substrate 100. A plurality of pad sections 204 is formed at the surface 200S1 of the coupling layer 203, for example, in row and column directions in an array manner. The plurality of pad sections 204 corresponds to one specific example of a “plurality of second bonding sections” in the embodiment according to the present disclosure. The plurality of pad sections 204 is correspondingly electrically coupled, through a via V2, to a plurality of circuits formed in the circuit layer 202.

The first substrate 100 and the second substrate 200 are directly bonded using metal-metal bonding or hybrid bonding or the like, and are electrically coupled to each other. Specifically, the first substrate 100 and the second substrate 200 are electrically coupled to each other through a plurality of pad sections 103 and 204 formed at a corresponding bonding surface (the surface 100S2 and the surface 200S1) in an array manner. In addition, within the first substrate 100 and the second substrate 200, the plurality of semiconductor elements formed in the first substrate 100 and the plurality of circuits formed in the second substrate 200 are electrically coupled to each other through the plurality of pad sections 103 and 204 formed at the corresponding bonding surface (the surface 100S2 and the surface 200S1) in an array manner.

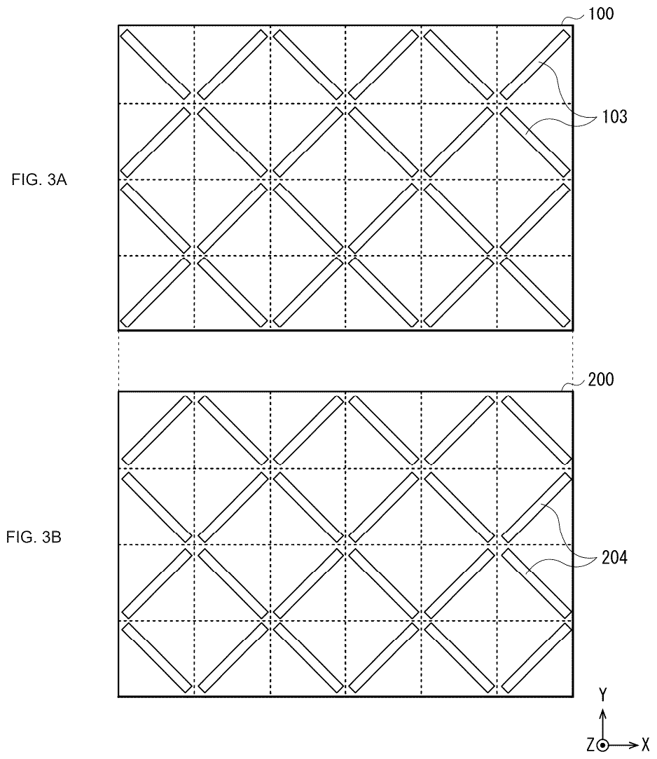

FIG. 2 is a diagram schematically illustrating one example of a planar layout of the plurality of pad sections 103 and 204 at the corresponding bonding surface (the surface 100S2 and the surface 200S1) of the stacked structure 1 illustrated in FIG. 1. FIG. 3 is a diagram illustrating one example of a layout of the pad sections 103 (A) at the first substrate 100 side and the pad sections 204 (B) at the second substrate 200 side.

In the stacked structure 1 according to the present embodiment, the plurality of pad sections 103 and 204 formed at the corresponding bonding surface (the surface 100S2 and the surface 200S1) of the first substrate 100 and the second substrate 200 each has a plane shape having a longitudinal direction and a transverse direction that are orthogonal to each other. In addition, the longitudinal direction of each of the plurality of pad sections 103 and 204 forms an angle of an absolute value greater than 0° and less than 90° relative to the array directions (a row direction (X-axis direction) and a column direction (Y-axis direction)) of the plurality of pad sections 103 and 204. Furthermore, a pair of adjacent pad sections 103 (or, pad sections 204) is substantially in mirror-image symmetry with each other.

Specifically, the plurality of pad sections 103 and 204 each has a rectangular shape. The long side of the rectangular shape forms an angle of, for example, 45° or 135° on an alternate basis relative to the individual array directions (the X-axis direction and the Y-axis direction) of the plurality of pad sections 103 and 204.

In addition, in the present embodiment, a pad section 103 and a pad section 204 that are opposed to each other are disposed such that the long sides of these pad sections are orthogonal to each other, between the first substrate 100 and the second substrate 200.

This configuration improves the bonding margin between the pad section 103 and the pad section 204 at the corresponding bonding surface (the surface 100S2 and the surface 200S1) of the first substrate 100 and the second substrate 200, which makes it possible to achieve pattern coupling with fine pitches of not more than 10 μm, for example.

Note that it is possible to use, for example, metal diffusion bonding, atomic diffusion bonding, surface activated bonding, plasma-activated bonding, or anodic bonding to bond the plurality of pad sections 103 and the plurality of pad sections 204 at corresponding bonding surfaces (the surface 100S2 and the surface 200S1).

### 1-2. Configuration of Semiconductor Device

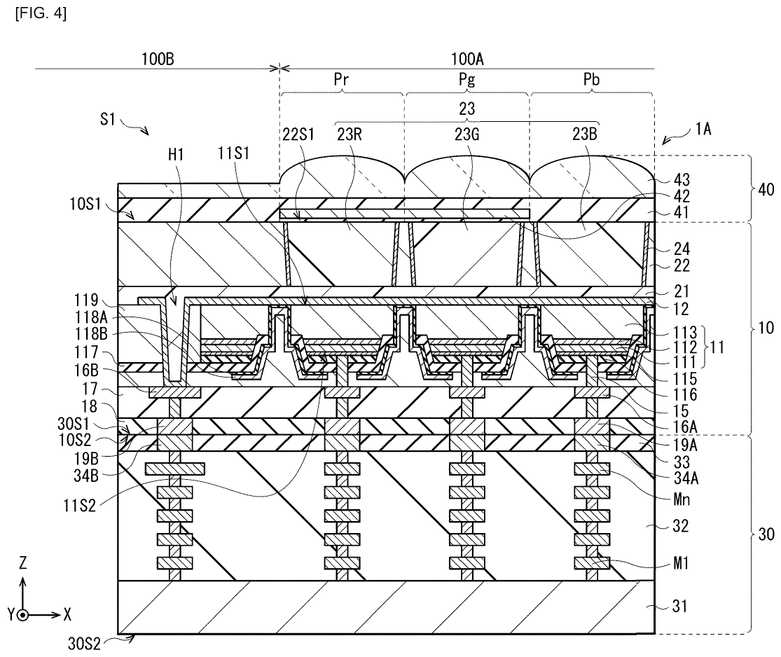

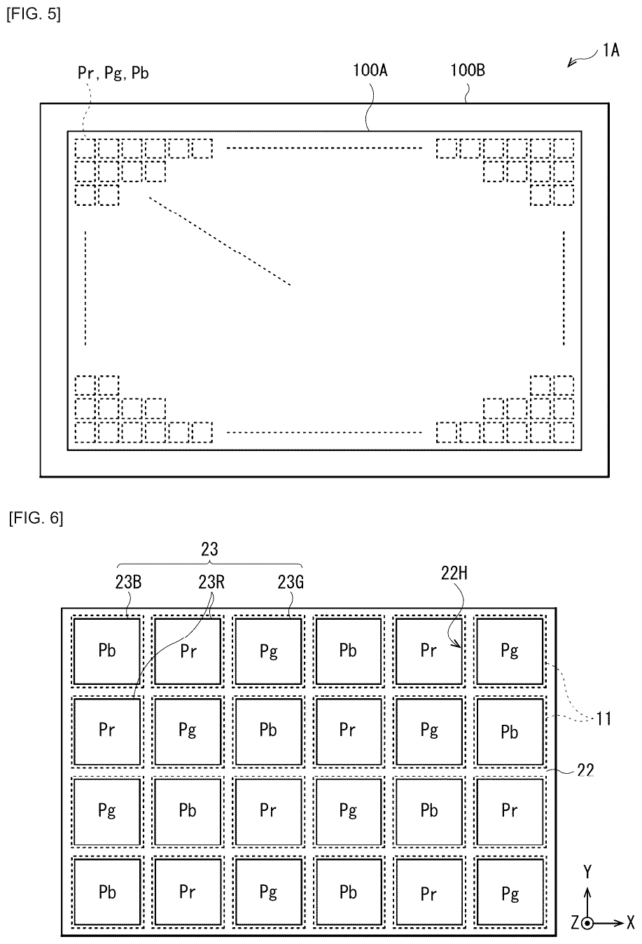

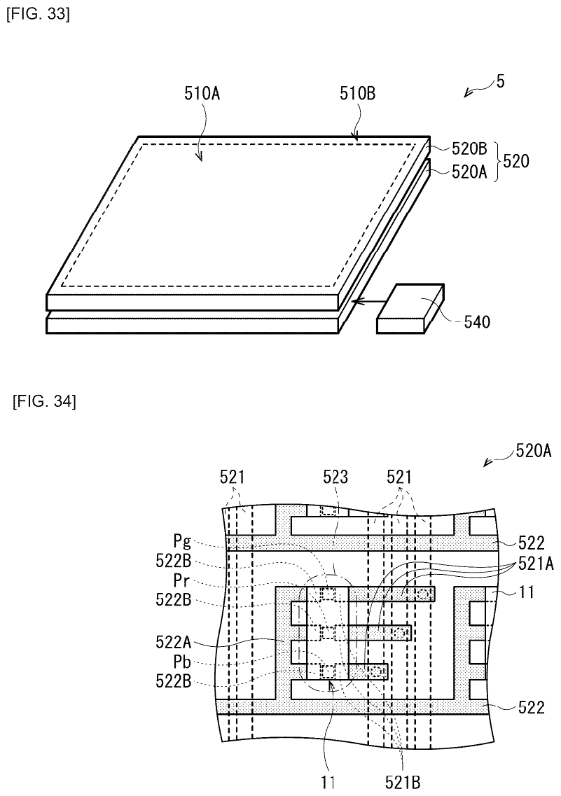

FIG. 4 is a sectional schematic view of one example of the configuration of a semiconductor device (light emission device 1A) according to the embodiment of the present disclosure. FIG. 5 is a diagram schematically illustrating one example of the planar configuration of the entire light emission device 1A illustrated in FIG. 4. The light emission device 1A is favorably applicable to an image display device (for example, an image display device 5, and see FIG. 33) that is a so-called LED display. The technique described above is applicable to, for example, the light emission device 1A.

The light emission device 1A is configured such that the element substrate 10 and a drive-circuit substrate 30 are bonded through hybrid bonding. The element substrate 10 includes a display region 100A in which a plurality of light emitting elements 11 is disposed in a two-dimensional array manner, and also includes a frame region 100B provided around the display region 100A. The element substrate 10 includes a surface 10S1 serving as a light-outputting surface and a surface 10S2 disposed on the opposite side from the surface 10S1. The drive-circuit substrate 30 is stacked at the surface 10S2 side of the element substrate 10. The drive-circuit substrate 30 includes a surface 30S1 that is opposed to the element substrate 10, and also includes a surface 30S2 disposed on the opposite side from the surface 30S1. The drive-circuit substrate 30 is provided with a plurality of drive circuits that controls drive of the plurality of light emitting elements 11 disposed in the display region 100A, for example.

In the light emission device 1A, the element substrate 10 corresponds to one specific example of a “first substrate” in the embodiment according to the present disclosure. The surface 10S1 corresponds to one specific example of a “first surface” in the embodiment according to the present disclosure. The surface 10S2 corresponds to one specific example of a “second surface” in the embodiment according to the present disclosure. The drive-circuit substrate 30 corresponds to one specific example of a “second substrate” in the embodiment according to the present disclosure. The surface 30S1 corresponds to one specific example of a “third surface” in the embodiment according to the present disclosure. The surface 30S2 corresponds to one specific example of a “fourth surface” in the embodiment according to the present disclosure.

The element substrate 10 includes the plurality of light emitting elements 11 obtained by separating a compound semiconductor layer extending in the display region 100A. The plurality of light emitting elements 11 has, for example, a substantially rectangular shape as illustrated in FIG. 6, and is disposed in the display region 100A, for example, in a row direction (for example, an X-axis direction) and a column direction (for example, a Y-axis direction) in an array manner. An electrode layer 12 that is continuous with the plurality of light emitting elements 11 is formed at the light extracting surface (surface 11S1) side of the plurality of light emitting elements 11. An electrode layer 115, an insulating layer 116, and a protection layer 117 each provided for each of the elements are formed at the surface 11S2 side of the plurality of light emitting elements 11. In addition, an insulation film 118A and a reflective film 118B that are continuous with the plurality of light emitting elements 11 are formed at the surface 11S2 side of the plurality of light emitting elements 11. The element substrate 10 further includes insulating layers 17 and 18 and an embedding layer 119 in which the plurality of light emitting elements 11 is embedded from the surface 10S2 side, and the insulating layers 17 and 18 and the embedding layer 119 are provided at the drive-circuit substrate 30 side. The embedding layer 119 includes a plug 15 provided for each of the elements. The insulating layer 17 includes a pad section 16A provided in the display region 100A and for each of the elements, and also includes a pad electrode 16B provided in the frame region 100B. The insulating layer 18 includes a pad section 19A provided in the display region 100A for each of the elements, and also includes a pad section 19B provided in the frame region 100B, thereby constituting a surface bonded to the drive-circuit substrate 30. At the surface 10S1 side, the element substrate 10 further includes a planarizing layer 21, a partition wall layer 22 having, for example, an aperture 22H and provided for each of the light emitting elements 11, and a wavelength converting layer 23 formed within the aperture 22H. A reflective film 24 is further provided between the partition wall layer 22 and the wavelength converting layer 23.

The light emitting element 11 corresponds to one specific example of a “semiconductor element” in the embodiment according to the present disclosure. The light emitting element 11 includes a solid-state light-emitting element that emits light having a predetermined wavelength band from the surface 11S1, and includes, for example, an LED (Light Emitting Diode) chip. The LED chip represents a chip in a state of being cut out from a wafer used for crystal growth, and does not represent a chip of a package type that is covered with formed resin or the like. The LED chip including a so-called micro LED having a small size of not less than 500 nm and not more than 100 μm, for example.

In the light emitting element 11, a first conductivity-type layer 111, an active layer 112, and a second conductivity-type layer 113 are layered in this order with the upper surface of the second conductivity-type layer 113 serving as the light-outputting surface (surface 11S1).

The first conductivity-type layer 111 includes an n-type GaN-based semiconductor material, for example. The active layer 112 has, for example, a multi quantum well structure in which InGaN and GaN are alternately stacked, and includes a light emitting region within a layer. Light having a blue band of not less than 430 nm and not more than 500 nm is taken out from the active layer 112, for example. In addition, light (ultraviolet light) having a wavelength, for example, corresponding to a ultraviolet region may be taken out from the active layer 112. The second conductivity-type layer 113 includes a p-type GaN-based semiconductor material, for example.

The electrode layer 12 is continuously formed at the surface 11S1 of each of the plurality of light emitting elements 11, and serves as a common electrode for the plurality of light emitting elements 11. The electrode layer 12 is in ohmic contact with the second conductivity-type layer 113, and includes, for example, a transparent electrode material such as zinc oxide (ZnO), ITO, indium zinc oxide (IZO), tin oxide (SnO), or TiO. In the frame region 100B, the electrode layer 12 penetrates through the protection layer 117 and the embedding layer 119, and is electrically coupled to a pad section 19B through an aperture H1 from which the pad section 19B is exposed at the bottom portion thereof.

The electrode layer 115 is formed at a lower surface (surface 11S2) of the first conductivity-type layer 111 of the light emitting element 11. The electrode layer 115 is in ohmic contact with the first conductivity-type layer 111, and is formed by using, for example, a transparent conductive material such as ITO or a multilayer film (Ni/Au) including nickel (Ni) and gold (Au), or the like.

The insulating layer 116 is provided at the electrode layer 115. The insulating layer 116 includes, for example, silicon oxide (SiO), silicon nitride (SiN), or the like.

The drive-circuit substrate 30 side of the light emitting element 11 has a mesa shape including the first conductivity-type layer 111, the active layer 112, and a portion of the second conductivity-type layer 113. The surface 11S2, and side surfaces of the first conductivity-type layer 111, the active layer 112, and a portion of the second conductivity-type layer 113 of the light emitting element 11 formed into the mesa shape are covered with the protection layer 117. The protection layer 117 includes, for example, silicon oxide (SiO), silicon nitride (SiN), or the like.

In addition, the side surface of the second conductivity-type layer 113 that is provided above the protection layer 117 and exposed from the protection layer 117 is covered with a stacked film including the insulation film 118A and the reflective film 118B. The stacked film is continuously formed over the plurality of light emitting elements 11. The stacked film has an aperture 118H at the surface 11S2 side of the light emitting element 11, and the plug 15 is formed within the aperture 118H.

The plug 15 is used to apply a voltage to the first conductivity-type layer 111 of each of the plurality of light emitting elements 11. The plug 15 is formed by using, for example, copper (Cu), aluminum (Al), tungsten (W), or silver (Ag), or an alloy of these elements, or the like.

The embedding layer 119 is used to embed the plurality of light emitting elements 11 and form a flat stacking surface at the drive-circuit substrate 30 side and over the display region 100A and the frame region 100B. In addition, in the frame region 100B, the embedding layer 119 forms a continuous flat surface at the surface 11S1 of the plurality of light emitting elements 11. The embedding layer 119 includes, for example, silicon oxide (SiO) or silicon nitride (SiN) or the like.

The insulating layer 17 is provided at the drive-circuit substrate 30 side of the embedding layer 119. A plurality of pad sections 16A each provided in the display region 100A for each of the light emitting elements 11A, the pad electrode 16B provided in the frame region 100B, and a via are formed within the insulating layer 17. The insulating layer 17 includes, for example, silicon oxide (SiO) or silicon nitride (SiN) or the like. The pad sections 16A, the pad electrode 16B, and the via are formed by using, for example, copper (Cu), aluminum (Al), tungsten (W), or silver (Ag), or an alloy of these elements.

Furthermore, the insulating layer 18 that constitutes the bonding surface bonded to the drive-circuit substrate 30 is formed at the drive-circuit substrate 30 side of the insulating layer 17. The plurality of pad sections 19A provided in the display region 100A for each of the light emitting elements 11A and the pad section 19B provided in the frame region 100B are formed so as to be embedded in the insulating layer 18. The insulating layer 18 includes, for example, silicon oxide (SiO) or silicon nitride (SiN) or the like. The pad sections 19A and 19B are formed by using, for example, copper (Cu).

The planarizing layer 21 is used to flatten the light extracting surface (surface 11S1) in the display region 100A including the plurality of light emitting elements 11 disposed in an array manner. The planarizing layer 21 includes, for example, silicon oxide (SiO), silicon nitride (SiN), or the like.

When the light emission device 1A is applied to the image display device 5, the partition wall layer 22 is used to suppress occurrence of mixture of colors due to leakage of light between adjacent RGB color pixels (a red pixel Pr, a green pixel Pg, and a blue pixel Pb). The partition wall layer 22 has, for example, the aperture 22H having a substantially rectangular shape and provided for each of the plurality of light emitting elements 11 disposed in an array manner, as illustrated in FIG. 6. The aperture 22H includes a surface sloped at less than 90° relative to a surface of the partition wall layer 22 that is opposed to the light emitting element 11 when viewed in cross section, for example. That is, when viewed in cross section, the partition wall layer 22 has a forward tapered shape between adjacent color pixels Pr, Pg, and Pb. It is preferable to form the partition wall layer 22 by using a material having high thermal conductivity and high electric conductivity. For example, the partition wall layer 22 is formed by using a metal material such as copper (Cu), aluminum (Al), gold (Au), nickel (Ni) or platinum (Pt).

The wavelength converting layer 23 is used to convert the light outputted from the plurality of light emitting elements 11 into light having a desired wavelength (for example, red (R)/green (G)/blue (B)) to output it, and is formed within the aperture 22H provided at the upper side of each of the light emitting elements 11. Specifically, a red wavelength converting layer 23R that converts the light outputted from the light emitting element 11 into light (red light) having a red band is provided at the red pixel Pr. A green wavelength converting layer 23G that converts the light outputted from the light emitting element 11 into light (green light) having a green band is provided at the green pixel Pg. A blue wavelength converting layer 23B that converts the light outputted from the light emitting element 11 into light (blue light) having a blue band is provided at the blue pixel Pb.

It is possible to form each of the wavelength converting layers 23R, 23G, and 23B by using a quantum dot corresponding to each of the colors. Specifically, in a case of obtaining red light, it is possible to select a quantum dot from among InP, GaInP, InAsP, CdSe, CdZnSe, CdTeSe, CdTe, or the like, for example. In a case of obtaining green light, it is possible to select a quantum dot from among InP, GaInP, ZnSeTe, ZnTe, CdSe, CdZnSe, CdS, CdSeS, or the like, for example. In a case of obtaining blue light, it is possible to make selection from among ZnSe, ZnTe, ZnSeTe, CdSe, CdZnSe, CdS, CdZnS, CdSeS, and the like. Note that, in a case where blue light is outputted from the light emitting element 11 as described above, it may be possible to form the blue wavelength converting layer 23B by using a resin layer having optical transparency.

The reflective film 24 is used to efficiently extract, from the light extracting surface (surface 22S1) of the wavelength converting layer 23, individual color light outputted from the light emitting element 11 and converted through the individual wavelength converting layers 23R, 23G, and 23B. The reflective film 24 is provided at the side surface of the aperture 22H. The reflective film 24 is formed by using a metal material having optical reflectivity. The metal material used to form the reflective film 24 includes, for example, a metal having high reflectivity in a visible-light region. Specifically, the material includes, for example, silver (Ag), aluminum (Al), copper (Cu), gold (Au), platinum (Pt), rhodium (Rh), an alloy of these metals, and the like.

Note that, in a case where the partition wall layer 22 is formed by using a metal material having optical reflectivity, it is not always necessary to form the reflective film 24.

It may be possible to further form an optical structure unit 40 at the light-outputting surface S1 side of the element substrate 10. The optical structure unit 40 includes a protection layer 41 formed over the display region 100A and the frame region 100B, a wavelength selection layer 42 formed within the protection layer 41, and an on-chip lens layer 43 formed at the protection layer 41.

The protection layer 41 is used to protect the front surface of the wavelength converting layer 23, and includes, for example, silicon oxide (SiO), silicon nitride (SiN), and the like.

Within the protection layer 41, the wavelength selection layer 42 is provided over the red pixel Pr and the green pixel Pg. The wavelength selection layer 42 is used to, for example, selectively reflect light (blue light) having a blue band. This configuration improves the color purity of the red light and the green light extracted from the red pixel Pr and the green pixel Pg, respectively.

The on-chip lens layer 43 is provided so as to cover the entire surface of the display region 100A and the frame region 100B. The on-chip lens layer 43 includes a material having optical transparency, and for example, includes a single layer film including any one of silicon oxide (SiO), silicon nitride (SiN), silicon oxynitride (SiCN), and the like, or includes a stacked film including two or more types of these elements.

The drive-circuit substrate 30 includes a drive circuit or the like that controls drive of the plurality of light emitting elements 11 disposed in the display region 100A. The drive-circuit substrate 30 includes: a support substrate 31; an interlayer insulating layer 32 provided at the support substrate 31 and including vias that electrically couple a plurality of wiring layers (for example, wiring layers M1, . . . , Mn) and wiring layers; and an insulating layer 33 that constitutes the bonding surface bonded to the element substrate 10. In the insulating layer 33, a plurality of pad sections 34A provided in the display region 100A for each of the light emitting elements 11A and a pad section 34B provided in the frame region 100B are embedded and formed in an insulating layer 34.

The interlayer insulating layer 32 includes, for example, silicon oxide (SiO), silicon nitride (SiN), or the like.

The vias that electrically couple the wiring layers (for example, wiring layers M1, . . . , Mn) and the wiring layers are formed by using, for example, copper (Cu), aluminum (Al), tungsten (W), silver (Ag), or an alloy of these elements. The insulating layer 33 includes, for example, silicon oxide (SiO), silicon nitride (SiN), or the like. The pad section 35 is formed by using copper (Cu), for example.

In the light emission device 1A, the plurality of pad sections 19A corresponds to one specific example of the “first bonding section” in the present embodiment, and the plurality of pad sections 34A corresponds to one specific example of the “second bonding section” in the present embodiment. The plurality of pad sections 19A and 34A each has a rectangular shape as illustrated, for example, in FIG. 2 and FIGS. 3A and 3B. The long side of the rectangular shape alternately forms an angle of, for example, 45° or 135° relative to the individual array directions (the X-axis direction and the Y-axis direction) of the light emitting elements 11, for example. In addition, the pad section 103 and the pad section 204 that are opposed to each other in a stacking direction (Z-axis direction) are disposed such that the long sides of these pad sections are orthogonal to each other. This configuration improves the bonding margin between the pad section 19A and the pad section 34A at the corresponding bonding surface (the surface 10S2 and the surface 30S1) of the element substrate 10 and the drive-circuit substrate 30, which makes it possible to achieve pattern coupling with fine pitches of not more than 10 μm, for example.

### 1-3. Workings and Effects

In the stacked structure 1 (and the light emission device 1A) according to the present embodiment, the plurality of pad sections 103 and 204 is provided at the corresponding bonding surface (the surface 100S2 and the surface 200S1) of the first substrate 100 and the second substrate 200 in row and column directions in an array manner, and each has a substantially rectangular shape having a long side and a short side that are orthogonal to each other, for example. In addition, the plurality of pad sections 103 and 204 is configured such that the long side of each of these pad sections forms an angle of an absolute value of, for example, 45° relative to the array direction (for example, the row direction (X-axis direction)) of the plurality of pad sections 103 and 204, and a pair of adjacent pad sections 103 (or, adjacent pad sections 204) is substantially in mirror-image symmetry with each other. This configuration improves the bonding margin between the pad section 19A and the pad section 34A that are opposed to each other at the bonding surfaces (the surface 100S2 and the surface 200S1). This will be described below.

In a display device using a self-illuminating light source such as a micro LED array for which increased luminance is demanded, an active matrix-type current supply is used to maximize its potential. However, it is still challenging to form a circuit at the front surface or the back surface of the LED substrate. Thus, it is necessary to use a technique of bonding with a backplane typified by a silicon (Si) substrate. This is because there are various types of issues in which the substrate itself on which the LED is formed is an electrical insulating body, or the property of crystal is not suitable for formation of a circuit, a through-via is difficult to be formed, or the like.

For this reason, a typical method is used such that an Si substrate on which a circuit is formed and an LED substrate are bonded together as in hybrid bonding or the like, to form a micro LED array substrate.

However, with this bonding method, it is difficult to bond all bonding points disposed in the plane because of releasing of stress due to a difference in properties between individual substrates, a difference in coefficients of linear expansion due to bonding temperatures, misalignment occurring due to the accuracy of a bonding device at the time of bonding, or the like. This results in a huge problem in terms of achieving high precision.

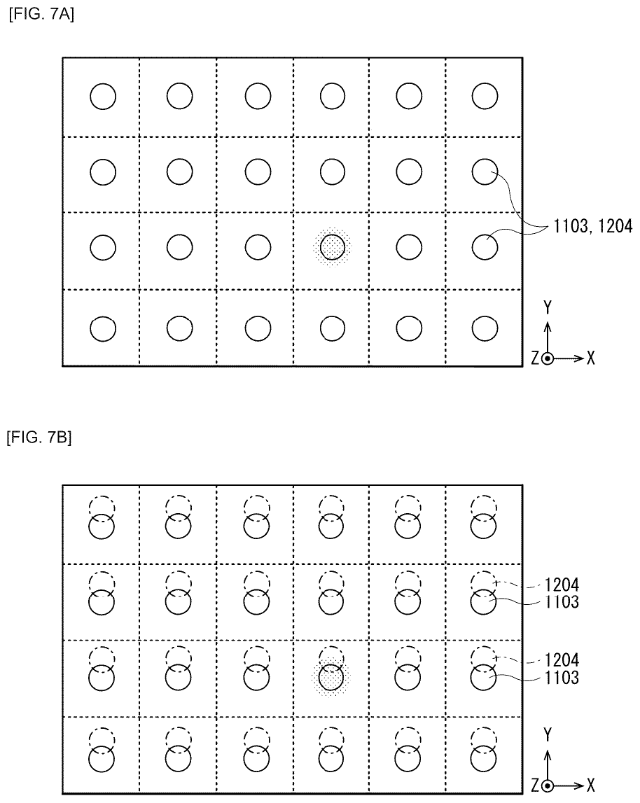

FIG. 7A is a diagram schematically illustrating one example of a layout of pad sections 1103 and 1204 at a bonding surface of a typical stacked structure according to a comparative example. FIG. 7B is a diagram illustrating the misalignment of bonding in the stacked structure illustrated in FIG. 7A. The shape of a typical bonding section used in bonding between substrates is, for example, a round shape as illustrated in FIG. 7A. In the pad section 1103 and 1204 having the round shape, the bonding margin for the misalignment of bonding is a dot-pattern region illustrated in FIGS. 7A and 7B.

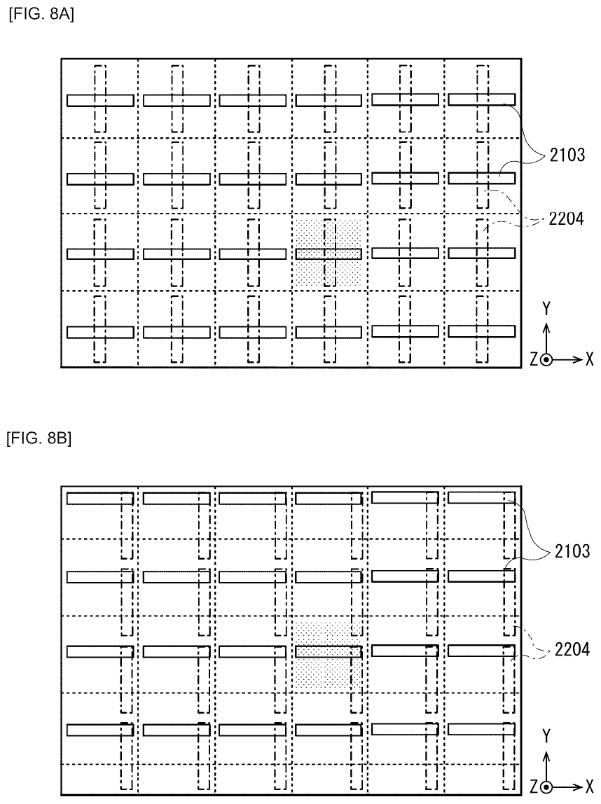

FIG. 8A is a diagram schematically illustrating another example of a layout of pad sections 2103 and 2204 at a bonding surface of a typical stacked structure according to a comparative example. FIG. 8B is a diagram illustrating misalignment of bonding in the stacked structure illustrated in FIG. 8A. In a case where a pad section (for example, a pad section 2103) at one side formed at a bonding surface has a rectangular shape with the row direction being a long side, and a pad section (for example, a pad section 2204) at the other side has a rectangular shape with the column direction being a long side, the bonding margin for the misalignment of bonding is a dot-pattern region illustrated in FIGS. 8A and 8B, and is expanded about 1.27-fold more than the pad sections 1103 and 1204 having the round shape.

FIG. 9 is a diagram schematically illustrating another example of a layout of pad sections 3103 and 3204 at a bonding surface of a typical stacked structure according to a comparative example. In a case where the areas of the pad sections 3103 and 3204 are simply expanded, the bonding margin for misalignment of bonding is expanded but the probability of occurrence of short circuit increases.

In contrast, the present embodiment is configured such that the plurality of pad sections 103 and 204 formed at the corresponding bonding surface (the surface 100S2 and the surface 200S1) of the first substrate 100 and the second substrate 200 each has a substantially rectangular shape having a long side and a short side that are orthogonal to each other, for example. In addition, the plurality of pad sections 103 and 204 each has a long side forming an angle of an absolute value of, for example, 45° relative to the array direction (for example, a row direction (X-axis direction)) of the plurality of pad sections 103 and 204. Furthermore, for example, a pair of adjacent pad sections 103 (or, pad sections 204) is substantially in mirror-image symmetry to each other.

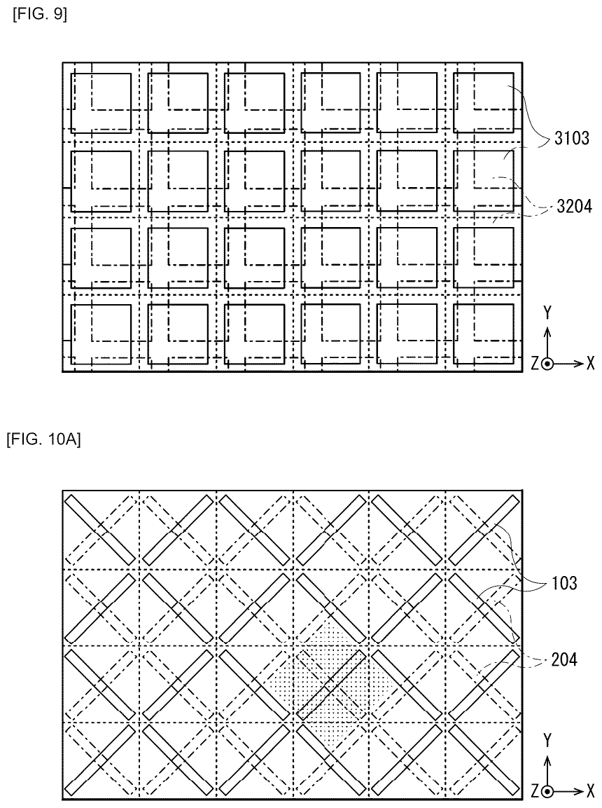

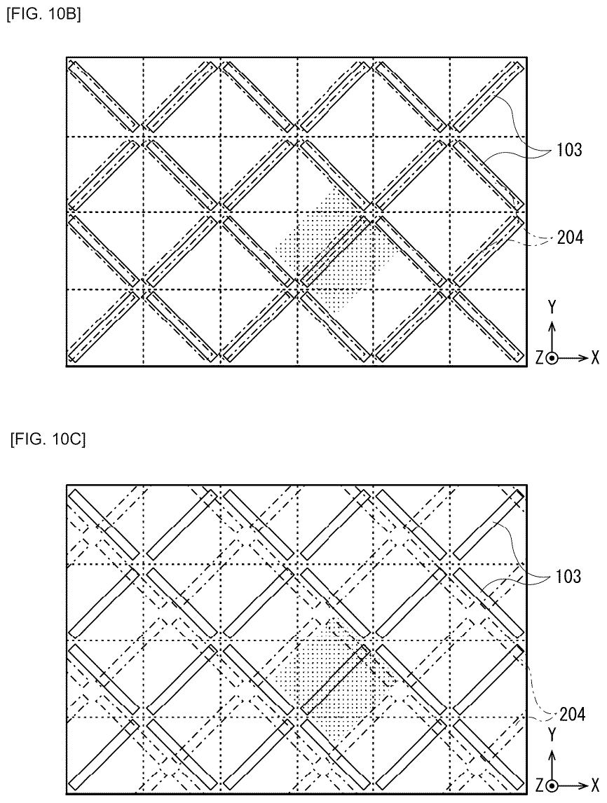

FIG. 10A is a diagram illustrating a layout of the plurality of pad sections 103 and 204 at the bonding surface (the surface 100S2 and the surface 200S1) of the stacked structure 1 according to the present embodiment, and also illustrating a bonding margin for misalignment of bonding. FIG. 10B is a diagram illustrating one example of misalignment of bonding in the stacked structure 1 illustrated in FIG. 10A. FIG. 10C is a diagram illustrating another example of misalignment of bonding in the stacked structure 1 illustrated in FIG. 10A. As described above, for example, the long sides of the plurality of pad sections 103 and 204 each form an angle of 45° or 135° relative to the row direction (X-axis direction). In addition, a pair of adjacent pad sections is substantially in mirror-image symmetry to each other. Furthermore, the pad section 103 and the pad section 204 are disposed so as to be orthogonal to each other. This configuration allows the bonding margin for misalignment of bonding to be further expanded. Specifically, the bonding margin is a dot-pattern region illustrated in FIGS. 10A to 10C. In addition, the bonding margin for misalignment of bonding in a row direction (X-axis direction) and in a column direction (Y-axis direction) is approximately 2.5-fold as compared with the pad sections 2103 and 2204 having a round shape illustrated in FIGS. 7A and 7B.

Thus, the stacked structure 1 according to the present embodiment (and the light emission device 1A) makes it possible to perform fine bonding with fine pitches of not more than 10 μm, for example. Thus, it is possible to provide an electronic device (for example, image display device) with high precision.

Next, description will be made of first to sixth modification examples and application example according to the present disclosure. Note that the same reference characters are attached to the corresponding constituent elements of the stacked structure 1 and the light emission device 1A according to the embodiment described above, and explanation thereof will not be repeated.

### 2. Modification Example

### 2-1. First Modification Example

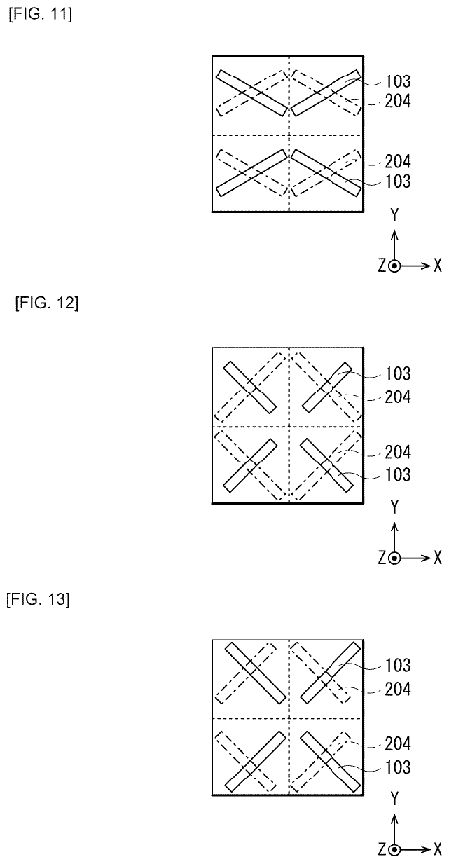

FIGS. 11 to 15 are diagrams schematically illustrating one example of a planar layout of pad sections according to the first modification example of the present disclosure.

In the embodiment described above, the plurality of pad sections 103 and 204 at the corresponding bonding surface (the surface 100S2 and the surface 200S1) of the stacked structure 1 each has a substantially rectangular shape, and includes a long side forming an angle of an absolute value of 45° relative to the array direction (for example, a row direction (X-axis direction)) of the plurality of pad sections 103 and 204. In addition, the pad section 103 and the pad section 204 that are opposed to each other are orthogonal to each other. However, the configuration is not limited to this.

For example, it is only necessary that the pad section 103 and the pad section 204 that are opposed to each other at the bonding surfaces (the surface 100S2 and the surface 200S1) intersect each other as illustrated in FIG. 11, and the angle formed by these pad sections is not limited. For example, the angle of a corresponding long side of the plurality of pad sections 103 and 204 may be formed such that a portion thereof is parallel to or orthogonal to the coefficient of linear expansion of individual substrates (the first substrate 100 and the second substrate 200).

In addition, the plurality of pad sections 103 and 204 at the bonding surfaces (the surface 100S2 and the surface 200S1) of the stacked structure 1 does not necessarily have the same size. For example, the long side at one (for example, the pad section 103) of them may be shorter than the long side at the other one (for example, the pad section 204) of them as illustrated in FIG. 12.

Furthermore, the intersecting position where the pad section 103 and the pad section 204 intersect each other at the bonding surfaces (the surface 100S2 and the surface 200S1) of the stacked structure 1 may be shifted from the center of gravity of each of the pad sections 103 and 204 as illustrated in FIG. 13, for example.

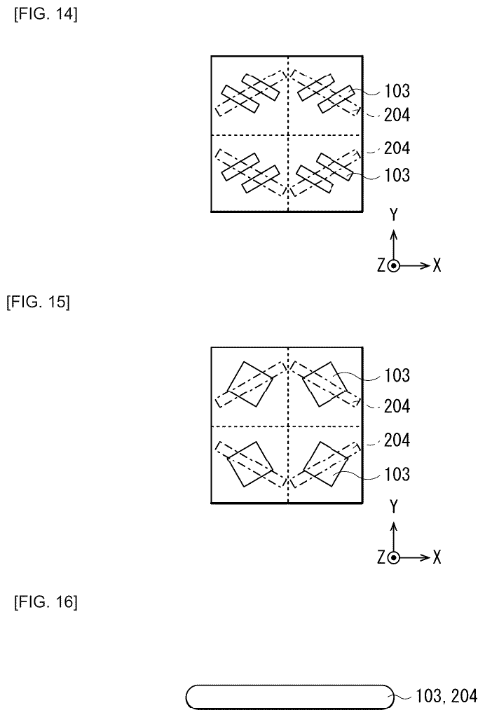

In addition, for example, it may be possible to employ a configuration in which one semiconductor element (for example, the light emitting element 11) is electrically coupled to a plurality of (for example, two) pad sections (for example, pad sections 103), and one pad section 204 is bonded to two pad sections 103 at bonding surfaces (the surface 100S2 and the surface 200S1) as illustrated, for example, in FIG. 14.

Furthermore, it is only necessary that either one of the plurality of pad sections 103 and 204 at the bonding surfaces (the surface 100S2 and the surface 200S1) of the stacked structure 1 has a plane shape having a longitudinal direction and a transverse direction. For example, as illustrated in FIG. 15, it may be possible to employ a configuration in which either one (for example, the plurality of pad sections 103) of the plurality of pad sections 103 and 204 has a substantially square shape, and the other (for example, the plurality of pad sections 204) has a rectangular shape.

### 2-2. Second Modification Example

FIGS. 16 to 21 are diagrams each illustrating one example of a plane shape of a pad section according to the second modification example of the present disclosure.

The embodiment described above gives an example in which the plurality of pad sections 103 and 204 having the longitudinal direction and the transverse direction has a substantially rectangular shape having a long side and a short side that are orthogonal to each other. However, the shape thereof is not limited to this. The pad section 103 (or the pad section 204) having the longitudinal direction and the transverse direction may include a straight region or a curved region over a portion of or all of the longitudinal direction and the transverse direction.

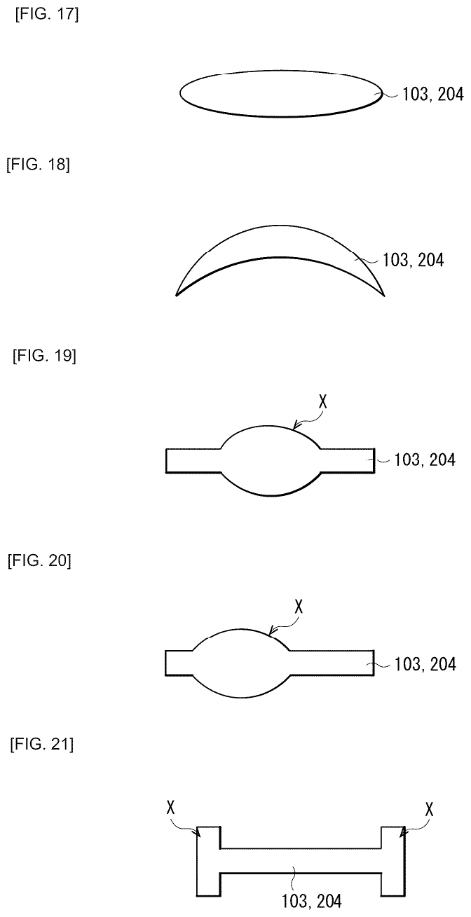

Specifically, the pad section 103 (or the pad section 204) having the longitudinal direction and the transverse direction may be configured such that an end portion of the substantially rectangular shape includes a curved surface as illustrated, for example, in FIG. 16. The pad section 103 (or the pad section 204) having the longitudinal direction and the transverse direction may have an oval shape as illustrated, for example, in FIG. 17. The pad section 103 (or the pad section 204) having the longitudinal direction and the transverse direction may have a crescent shape as illustrated, for example, in FIG. 18.

The pad section 103 (or the pad section 204) having the longitudinal direction and the transverse direction may have, for example, a shape obtained by combining two different types of shapes, and for example, may have a shape obtained by combining a rectangular shape and a round shape. Specifically, the pad section 103 (or the pad section 204) having the longitudinal direction and the transverse direction may be configured, for example, such that a wide part X having a round shape is provided substantially at the center of a rectangular shape as illustrated, for example, in FIG. 19. In addition, the wide part X may be provided at a position disposed more toward an end of the rectangular shape as illustrated, for example, in FIG. 20. Furthermore, the pad section 103 (or the pad section 204) having the longitudinal direction and the transverse direction may be configured, for example, such that the wide part X having a rectangular shape is provided, for example, at both ends of the rectangular shape as illustrated in FIG. 21.

### 2-3. Third Modification Example

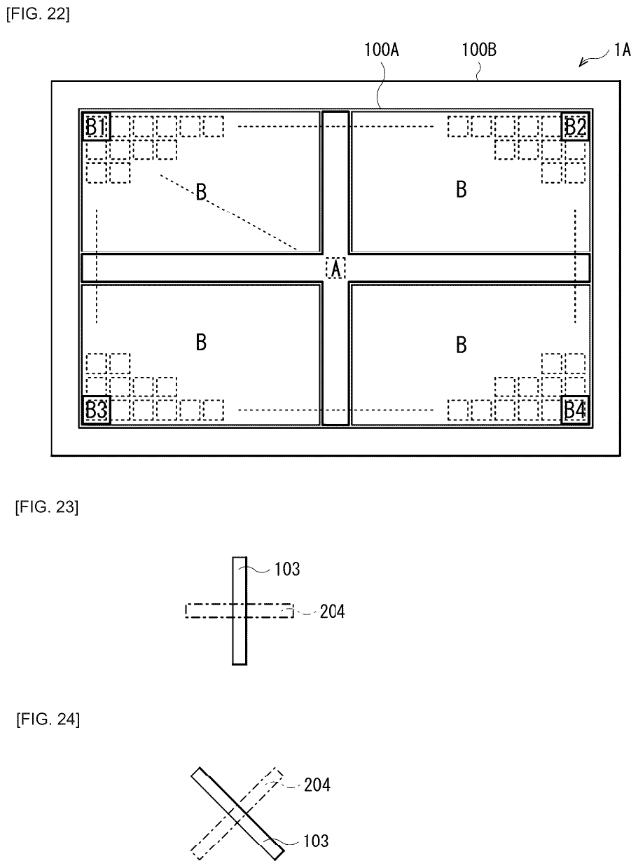

FIG. 22 is a diagram schematically illustrating the planar configuration of an entire stacked structure (for example, light emission device 1A) according to the third modification example of the present disclosure, and also illustrating a region A and a region B of the display region 100A.

The embodiment described above gives an example in which, in the display region 100A, the longitudinal direction of each of the plurality of pad sections 103 and 204 forms an angle of an absolute value greater than 0° and less than 90° relative to the array directions (the row direction (X-axis direction) and the column direction (Y-axis direction)) of the plurality of pad sections 103 and 204, and a pair of adjacent pad sections 103 (or, pad sections 204) is substantially in mirror-image symmetry to each other. However, the configuration is not limited to this. For example, pad sections 103 and 204 having a long side parallel to a row direction (X-axis direction) or a column direction (Y-axis direction) as illustrated, for example, in FIG. 23 may be disposed in the region A having a substantially cross-shape and extending at the center of the display region 100A and from the center toward the row direction (X-axis direction) or the column direction (Y-axis direction). Pad sections 103 and 204 having a long side parallel to or orthogonal to the coefficient of linear expansion of a corresponding substrate (the first substrate 100 and the second substrate 200) as illustrated, for example, in FIG. 24 are disposed in regions B separated by the region A, a pair of adjacent bonding sections of the pad sections 103 and 204 being in substantially in mirror-image symmetry.

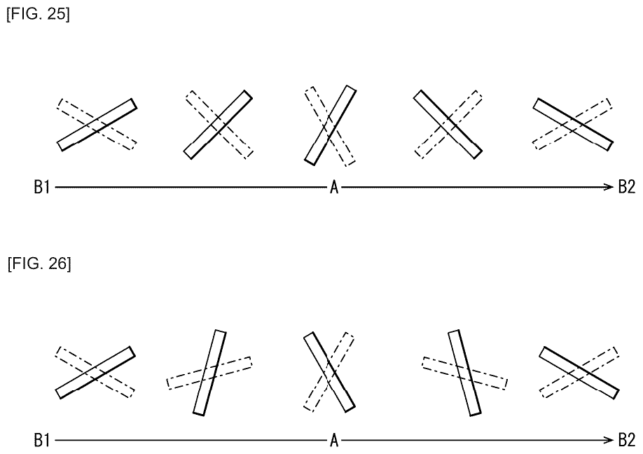

In addition, the plurality of pad sections 103 and 204 may be configured such that intersecting angles differ. Specifically, as illustrated in FIG. 25, it may be possible to employ a configuration in which long sides of the plurality of pad sections 103 and 204 periodically change, for example, with respect to the array directions (the X-axis direction and the Y-axis direction) of the light emitting element 11 from B1 toward B2 (or from B1 toward B3, or from B2 toward B4, or from B3 toward B4), for example. Alternatively, the plurality of pad sections 103 and 204 may have rotation symmetry. Specifically, as illustrated in FIG. 26, it may be possible to employ a configuration in which long sides of the plurality of pad sections 103 and 204 periodically rotate, for example, with respect to the array directions (the X-axis direction and the Y-axis direction) of the light emitting element 11 from B1 toward B2 (or from B1 toward B3, or from B2 toward B4, or from B3 toward B4), for example. In a case of the array as described above, a pair of pad sections 103 (or a pair of pad sections 204) disposed symmetrically with respect to the center of the display region 100A is substantially in mirror-image symmetry.

### 2-4. Fourth Modification Example

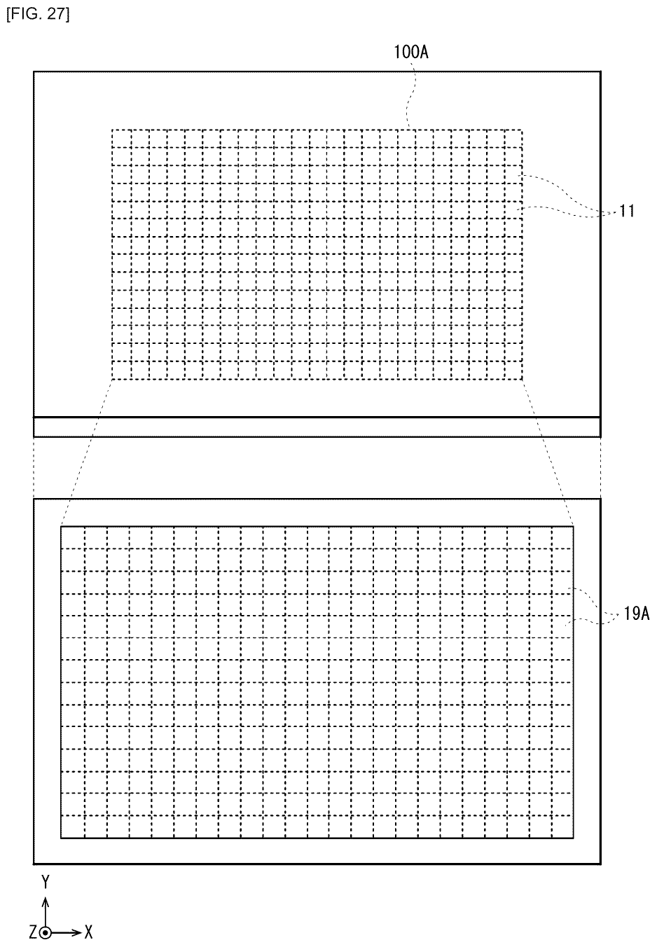

FIGS. 27 to 29 are diagrams each illustrating one example of a relationship between the arrangement region of the plurality of pad sections 19A at a bonding surface (surface 10S2) and the display region 100A configured such that a plurality of light emitting elements of the semiconductor device (for example, light emission device 1A) according to the fourth modification example of the present disclosure is arrayed in an array manner.

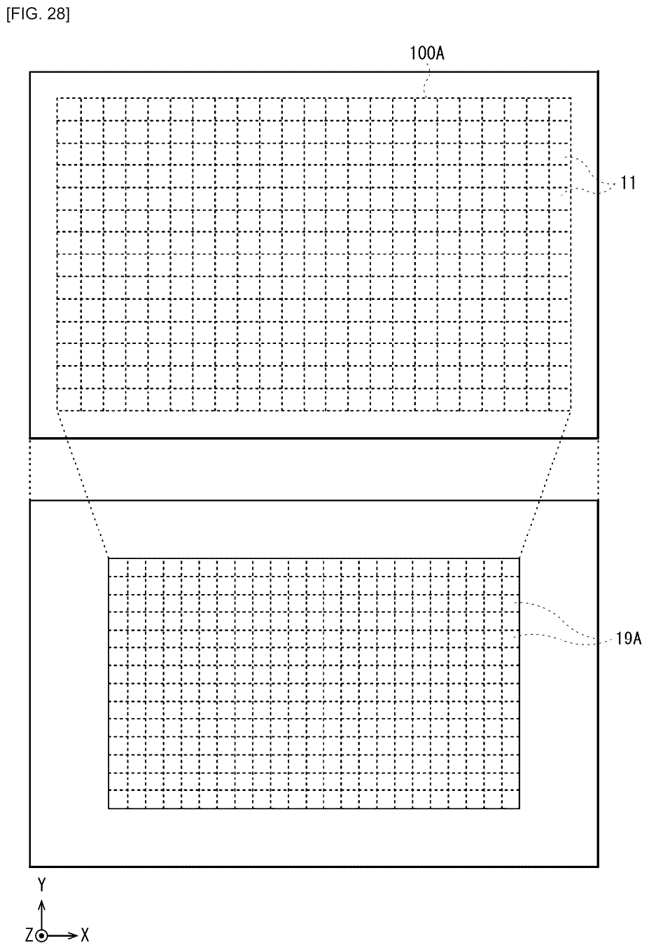

The embodiment described above gives an example in which the display region 100A configured such that the plurality of light emitting elements is arrayed in an array manner is aligned with the arrangement region of the plurality of pad sections 19A at the bonding surface (surface 10S2). In other words, the embodiment described above gives an example in which the array pitch of the plurality of light emitting elements 11 and the array pitch of the plurality of pad sections 19A are substantially the same. However, the configuration is not limited to this. For example, the array pitch of the plurality of light emitting elements 11 may be narrower than the array pitch of the plurality of pad sections 19A, as illustrated in FIG. 27. In addition, for example, the array pitch of the plurality of light emitting elements 11 may be wider than the array pitch of the plurality of pad sections 19A, as illustrated in FIG. 28. In this manner, it is possible to increase or reduce the cycle of the array pitch of the plurality of pad sections 19A depending on the plurality of pad sections 19A.

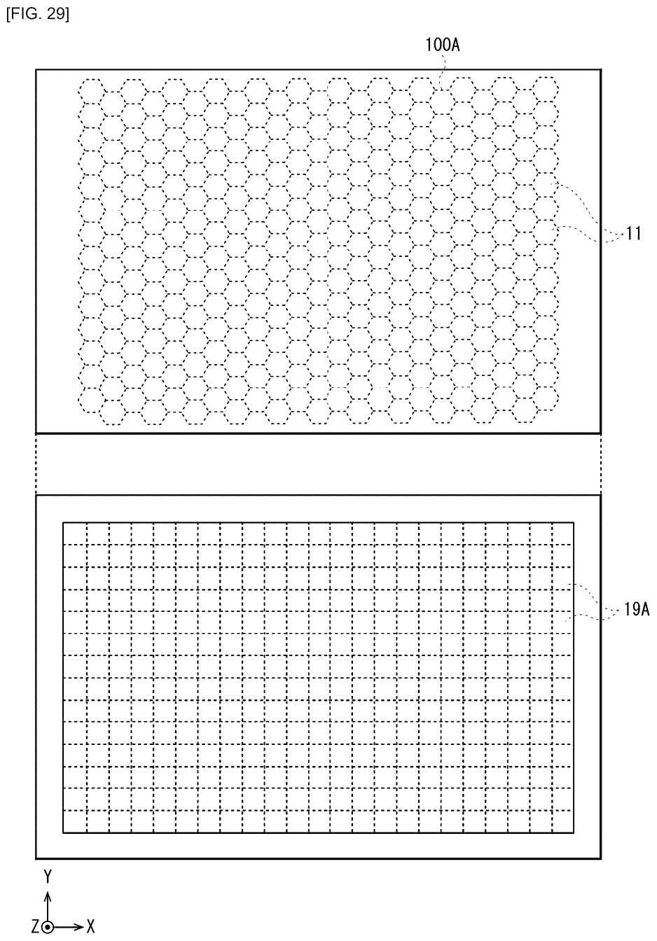

Furthermore, the plurality of light emitting elements 11 may each have a substantially regular hexagonal shape, and may be disposed, for example, in a honeycomb shape as illustrated, for example, in FIG. 29. It is possible to convert the array cycle disposed in the honeycomb shape as described above, for example, into a row-column manner by the plurality of pad sections 19A.

### 2-5. Fifth Modification Example

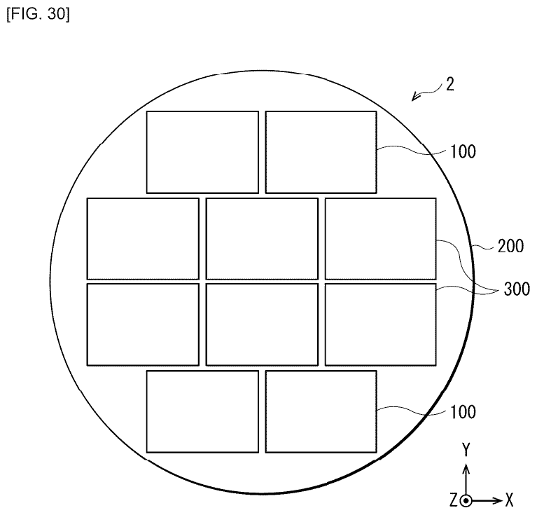

FIG. 30 is a schematic plan view used to describe the schematic configuration of a stacked structure (stacked structure 2) according to the fifth modification example of the present disclosure.

The embodiment described above gives an example in which the first substrate 100 and the second substrate 200 that constitute the stacked structure 1 have the same size. However, the configuration is not limited to this. It may be possible to employ a configuration in which the stacked structure 2 according to the present modification example uses the second substrate 200 larger than the first substrate 100, a plurality of first substrates 100 is stacked at the second substrate 200, a third substrate 300 is further stacked at the second substrate 200, and the third substrate 300 is provided with a semiconductor element having a function similar to or a function differing from the semiconductor element provided, for example, in the first substrate 100. In addition to the light emitting element, the semiconductor elements provided in the first substrate 100 and the third substrate 300 include a light receiving element, a memory element, or the like, for example.

### 2-6. Sixth Modification Example

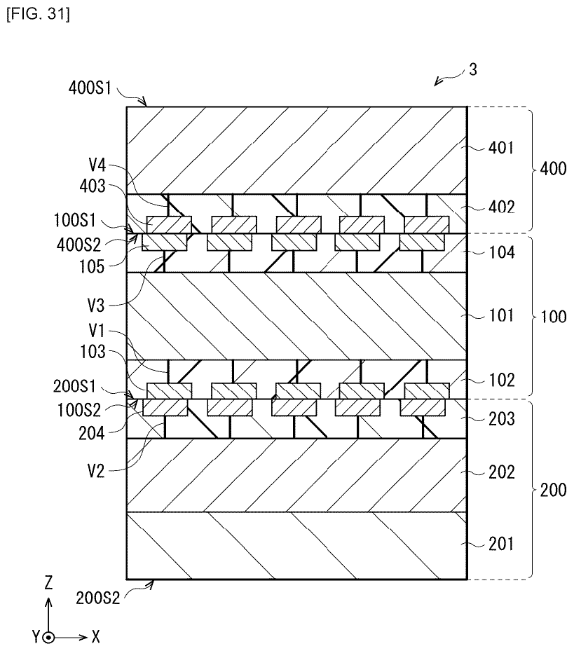

FIG. 31 is a sectional schematic view of one example of the schematic configuration of a stacked structure (stacked structure 3) according to the sixth modification example of the present disclosure.

The embodiment described above gives an example in which two substrates of the first substrate 100 and the second substrate 200 are stacked. However, the configuration is not limited to this. Three or more substrates may be stacked. The stacked structure 3 according to the present modification example is configured such that a fourth substrate 400 is further stacked at the surface 100S1 of the first substrate 100.

The first substrate 100 according to the present modification example further includes a coupling layer 104 provided at the surface 100S1 and constituting a surface bonded to the fourth substrate 400. A plurality of pad sections 105 is formed at the surface 100S1 constituted by the coupling layer 104, for example, in row and column directions in an array manner. For example, the plurality of pad sections 105 is correspondingly electrically coupled, through a via V3, to the plurality of semiconductor elements formed in the semiconductor layer 101.

For example, the fourth substrate 400 includes a semiconductor layer 401 in which a plurality of semiconductor elements (not illustrated) having a function similar to or a function differing from the semiconductor element provided in the first substrate 100 is formed, for example, in row and column directions in an array manner, and also includes a coupling layer 402 that constitutes a surface (surface 400S2) bonded to the first substrate 100. A plurality of pad sections 403 is formed at the surface 400S2 of the coupling layer 402, for example, in row and column directions in an array manner. The plurality of pad sections 403 is correspondingly electrically coupled, through a via V4, to the plurality of semiconductor elements formed in the semiconductor layer 401.

In the present modification example, the plurality of pad sections 105 and 403 formed at the corresponding bonding surfaces (the surface 100S1 and the surface 400S2) of the first substrate 100 and the fourth substrate 400 each has a plane shape having a longitudinal direction and a transverse direction that are, for example, orthogonal to each other, as with the plurality of pad sections 105 and 403 formed at the corresponding bonding surfaces (the surface 100S2 and the surface 200S1) of the first substrate 100 and the second substrate 200. In addition, the longitudinal direction of the plurality of pad sections 105 and 403 forms an angle of an absolute value greater than 0° and less than 90° relative to the array directions (the row direction (X-axis direction) and the column direction (Y-axis direction)) of the plurality of pad sections 105 and 403. Furthermore, for example, a pair of adjacent pad sections 103 (or, pad sections 204) is substantially in mirror-image symmetry to each other.

Specifically, the plurality of pad sections 105 and 403 each has a rectangular shape, and the long side thereof alternately forms an angle of, for example, 45° or 135° relative to the array direction (the X-axis direction and the Y-axis direction) of each of the plurality of pad sections 105 and 403.

In addition, in the present modification example, between the first substrate 100 and the fourth substrate 400, the pad section 105 and a pad section 2403 that are opposed to each other are configured such that the long sides of these pad sections are disposed so as to intersect each other. This configuration improves the bonding margin between the pad section 105 and the pad section 403 at the corresponding bonding surfaces (the surface 100S1 and the surface 400S2) of the first substrate 100 and the fourth substrate 400, which makes it possible to achieve pattern coupling with fine pitches of not more than 10 μm, for example.

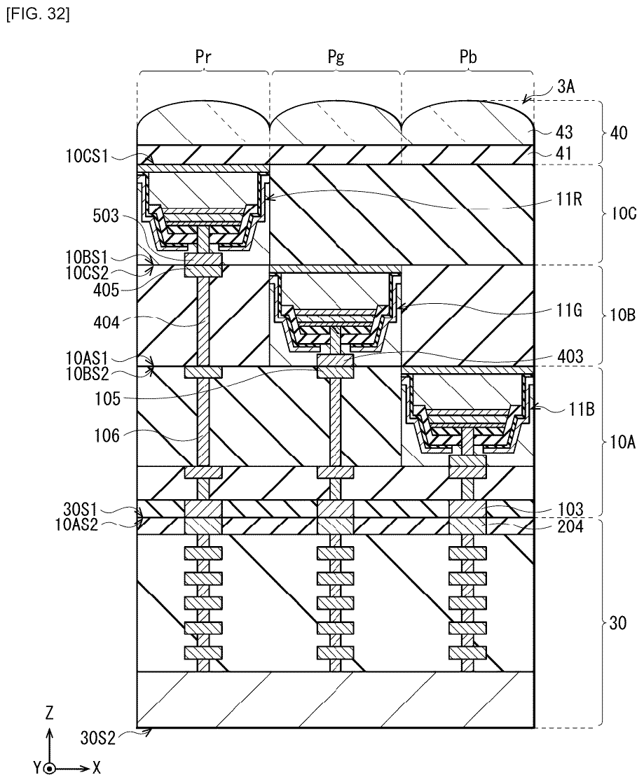

FIG. 32 is a diagram schematically illustrating one example of the configuration in cross section of a semiconductor device (light emission device 3A) according to the sixth modification example of the present disclosure. The light emission device 3A is a device to which the technique according to the present modification example described above is applied, and is favorably applicable to an image display device (for example, the image display device 5) that is a so-called LED display, as with the light emission device 1A according to the embodiment described above.

The light emission device 3A is configured such that element substrates 10A, 10B, and 10C are stacked in this order at the drive-circuit substrate 30. A plurality of light emitting elements 11B that outputs blue light is disposed at the element substrate 10A in a two-dimensional array manner, for example. A plurality of light emitting elements 11G that outputs green light is disposed at the element substrate 10B in a two-dimensional array manner, for example. A plurality of light emitting elements 11R that outputs red light is disposed at the element substrate 10C in a two-dimensional array manner, for example. In the light emission device 3A, the drive-circuit substrate 30 and the element substrate 10A are bonded through hybrid bonding. In addition, the element substrate 10A and the element substrate 10B are bonded through hybrid bonding. Furthermore, the element substrate 10B and the element substrate 10C are bonded through hybrid bonding.

In the light emission device 3A, the drive-circuit substrate 30 and the element substrate 10B that are stacked with the element substrate 10A being interposed between them are electrically coupled to each other through a through wiring 106. The drive-circuit substrate 30 and the element substrate 10C that are stacked with the element substrates 10A and 10B being interposed between them are electrically coupled to each other through a through wiring 404.

### 3. Application Example

### First Application Example

FIG. 33 is a perspective view of one example of the schematic configuration of an image display device (image display device 5). The image display device 5 is a so-called LED display, and employs the light emission device (for example, the light emission device 1A) according to the present disclosure as a display pixel. The image display device 5 includes a display panel 520 and a control circuit 540 that drives the display panel 520 as illustrated in FIG. 33, for example.

The display panel 520 is obtained by stacking a package substrate 520A and a counter substrate 520B together. The front surface of the counter substrate 520B serves as a video display surface. The counter substrate 520B includes a display region (display region 510A) at the middle portion, and also includes, around this display region, a frame region 510B serving as a non-display region.

FIG. 34 is a diagram illustrating one example of a wiring layout in a region of a front surface, at the counter substrate 520B side, of the package substrate 520A, this region corresponding to the display region 510A. In the region of the front surface of the package substrate 520A that corresponds to the display region 510A, a plurality of data wirings 521 is formed so as to extend in a predetermined direction and is disposed in parallel at predetermined pitches, as illustrated, for example, in FIG. 34. In addition, in the region of the front surface of the package substrate 520A that corresponds to the display region 510A, a plurality of scan wirings 522 is further formed so as to extend in a direction intersecting (for example, orthogonal to) the data wirings 521, for example, and is disposed in parallel at predetermined pitches. The data wirings 521 and the scan wirings 522 include, for example, an electrically conductive material such as Cu.

The scan wirings 522 are formed, for example, at the outermost layer, and for example, are formed at an insulating layer (not illustrated) formed at the front surface of the base member. Note that the base member of the package substrate 520A includes, for example, a silicon substrate or a resin substrate or the like. In addition, the insulating layer on the base member includes, for example, SiN, SiO, aluminum oxide (AIO), or a resin material. Furthermore, the data wirings 521 are formed in a layer (for example, a layer below the outermost layer) differing from the outermost layer including the scan wiring 522, and for example, are formed in the insulating layer on the base member.

A display pixel 523 is disposed at or around a portion where the data wiring 521 and the scan wiring 522 intersect each other, and a plurality of the display pixels 523 is disposed in the display region 510A in a matrix manner. The color pixels Pr, Pg, and Pb of the light emission device 1A are each mounted at the individual display pixels 523, for example.

The light emission device 1A includes a pair of terminal electrodes provided for each of the color pixels Pr, Pg, and Pb, or a terminal electrode of which one side is common and the other side is provided for each of the color pixels Pr, Pg, and Pb. In addition, the terminal electrode at one side is electrically coupled to the data wiring 521, whereas the terminal electrode at the other side is electrically coupled to the scan wiring 522. For example, the terminal electrode at one side is electrically coupled to a pad electrode 521B at the top end of a branch 521A provided in the data wiring 521. In addition, for example, the terminal electrode at the other side is electrically coupled to a pad electrode 522B at the top end of a branch 522A provided in the scan wiring 522.

Each of the pad electrodes 521B and 522B is formed, for example, at the outermost layer, and is provided at a portion where each of the light emission devices 1A is mounted, as illustrated in FIG. 34, for example. Here, the pad electrodes 521B and 522B include, for example, an electrically conductive material such as Au (gold).

In addition, for example, a plurality of pillars (not illustrated) that restricts the distance between the package substrate 520A and the counter substrate 520B is provided at the package substrate 520A. The pillars may be provided in a region that is opposed to the display region 510A, or may be provided in a region that is opposed to the frame region 510B.

The counter substrate 520B includes, for example, a glass substrate, or a resin substrate, or the like. The front surface of the counter substrate 520B at the light emission device 1A side may be flat. However, it is preferable that this front surface be a rough surface. This rough surface may be provided over the entire region that is opposed to the display region 510A, or may be provided only over the region that is opposed to the display pixel 523. This rough surface has fine projections and depressions, and light outputted from the color pixels Pr, Pg, and Pb enters this rough surface. It is possible to form the projections and depressions of the rough surface by using sandblasting, dry etching, or the like, for example.

The control circuit 540 drives each of the display pixels 523 (each of the light emission devices 1A) on the basis of a picture signal. The control circuit 540 includes a data driver that drives the data wiring 521 coupled to the display pixel 523, and a scan driver that drives the scan wiring 522 coupled to the display pixel 523. For example, the control circuit 540 may be provided separately from the display panel 520 so as to be coupled to the package substrate 520A through a wiring, or may be mounted at the package substrate 520A, as illustrated in FIG. 33.

### Second Application Example

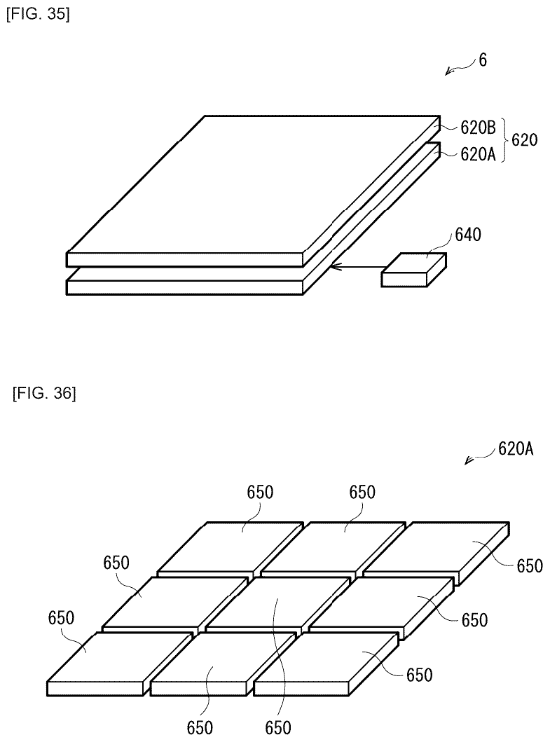

FIG. 35 is a perspective view of another configuration example (image display device 6) of an image display device using the light emission device (for example, the light emission device 1A) according to the present disclosure. The image display device 6 is a so-called tiling display using a plurality of light emission devices using an LED as a light source. The image display device 6 includes a display panel 620 and a control circuit 640 that drives the display panel 620 as illustrated in FIG. 35, for example.

The display panel 620 is obtained by stacking a package substrate 620A and a counter substrate 620B together. The front surface of the counter substrate 620B serves as a video display surface. The counter substrate 620B includes a displaying unit (not illustrated) at the middle portion, and includes, around this displaying unit, a frame portion (not illustrated) that is a non-display region. The counter substrate 620B is disposed at a position that is opposed to the package substrate 620A with a predetermined space being provided between them, for example. Note that the counter substrate 620B may be in contact with the upper surface of the package substrate 620A.

FIG. 36 is a diagram schematically illustrating one example of the configuration of the package substrate 620A. The package substrate 620A includes a plurality of unit substrates 650 that is arrayed in a tile manner as illustrated in FIG. 36, for example. Note that FIG. 36 shows an example in which the package substrate 620A includes nine unit substrates 650. However, the number of unit substrates 650 may be ten or more, or may be eight or less.

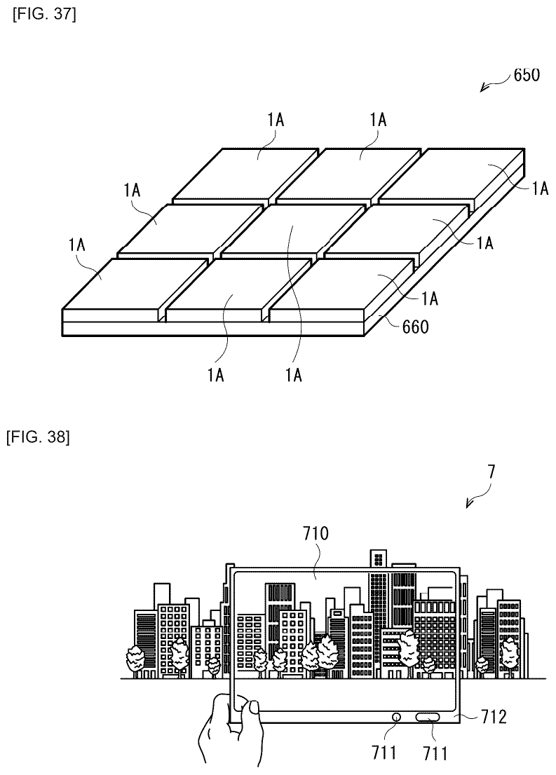

FIG. 37 is a diagram illustrating one example of the configuration of the unit substrate 650. For example, the unit substrate 650 includes the plurality of light emission devices 1A that is arrayed in a tile manner, and a support substrate 660 that supports each of the light emission devices 1A. Each of the unit substrates 650 further includes a control board (not illustrated). The support substrate 660 includes, for example, a metal frame (metal sheet), or a wiring substrate, or the like. When including a wiring substrate, the support substrate 660 is able to also work as a control board. At this time, the support substrate 660, the control board, or both of them are electrically coupled to each of the light emission devices 1A.

### Third Application Example

FIG. 38 is a diagram illustrating the external appearance of a transparent display 7. The transparent display 7 includes, for example, a displaying unit 710, an operation unit 711, and a housing 712. The light emission device (for example, light emission device 1A) according to the present disclosure is used in the displaying unit 710. The transparent display 7 makes it possible to display an image or character information while allowing the background of the displaying unit 710 to pass through.

In the transparent display 7, a substrate having optical transparency is used for the package substrate. Each electrode provided in the light emission device 1A is formed by using an electrically conductive material having optical transparency as with the package substrate. Alternatively, each electrode supplements a width of the wiring or reduces a thickness of the wiring to achieve a less-visible structure. In addition, for example, by stacking a liquid crystal layer including a drive circuit, the transparent display 7 makes it possible to achieve black display. Furthermore, by controlling the light orientation direction of liquid crystal, the transparent display makes it possible to switch between transmission and black display.

These are descriptions of the present technology using the embodiment, the first to sixth modification examples, and the application examples. However, the present technology is not limited to the embodiment described above and the like. Various modifications are possible. For example, as an example, the embodiment and the like give the light emission device as a semiconductor device. However, the semiconductor device to which the present technology is applied is not limited to this. For example, it is possible to apply the present technology to a photodetector including, for example, a light receiving element as a semiconductor element or to a storage device including a memory element or the like, and it is possible to obtain similar effects.

In addition, the embodiment and the like described above give an example in which light outputted from the light emitting element 11 is blue light or ultraviolet light. However, the light is not limited to this. For example, the light emission device 1A is able to use a light emitting element that outputs two or more types of light such as blue light and green light, ultraviolet light and green light, or the like.

Furthermore, the embodiment and the like described above specifically list each of the members that constitute the light emission device 1A and the like. However, it is not necessary to include all the members. In addition, other members may be further provided.

Note that the effects described in the present Description are given as examples, and are not given for the purpose of limitation. Other effects may be possible.

The present technology is able to employ the following configuration. The present technology having the following configurations makes it possible to improve the bonding margin between the first bonding section and the second bonding section, which makes it possible to achieve fine bonding between the first substrate and the second substrate.
(1)
   A stacked structure including:
   a first substrate including a first surface and a second surface that are opposed to each other, the first substrate including a first array in which a plurality of first bonding sections is provided at the second surface in a row direction and a column direction in an array manner; and
   a second substrate including a third surface opposed to the second surface and a fourth surface disposed on an opposite side from the third surface, the second substrate including a second array in which a plurality of second bonding sections is provided at the third surface in the row direction and the column direction in an array manner, the plurality of second bonding sections being correspondingly bonded to the plurality of first bonding sections, in which
   the plurality of first bonding sections, the plurality of second bonding sections, or both of the plurality of first bonding sections and the plurality of second bonding sections each have a plane shape having a longitudinal direction and a transverse direction that intersect each other, and
   of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.
(2)
   The stacked structure according to (1), in which the first substrate and the second substrate are bonded through hybrid bonding.
(3)
   The stacked structure according to (1) or (2), in which the first substrate and the second substrate have respective coefficients of linear expansion differing from each other.
(4)
   The stacked structure according to any one of (1) to (3), in which the first substrate, the second substrate, or both of the first substrate and the second substrate include a semiconductor substrate.
(5)
   The stacked structure according to any one of (1) to (4), in which the longitudinal direction of the plurality of bonding sections having the longitudinal direction and the transverse direction is parallel to or orthogonal to a linear expansion direction of each of the first substrate and the second substrate.
(6)
   The stacked structure according to any one of (1) to (5), in which the plurality of bonding sections having the longitudinal direction and the transverse direction includes a straight region in at least a portion of the longitudinal direction and the transverse direction.
(7)
   The stacked structure according to any one of (1) to (6), in which the plurality of bonding sections having the longitudinal direction and the transverse direction includes a curved region in at least a portion of the longitudinal direction and the transverse direction.
(8)
   The stacked structure according to any one of (1) to (7), in which the plurality of bonding sections having the longitudinal direction and the transverse direction has a substantially rectangular shape having long sides and short sides.
(9)
   The stacked structure according to (8), in which the plurality of bonding sections having the longitudinal direction and the transverse direction includes a wide part at a portion of the long sides that are opposed to each other.
(10)
   The stacked structure according to (9), in which the wide part has a substantially round shape.
(11)
   The stacked structure according to any one of (1) to (10), in which the plurality of bonding sections having the longitudinal direction and the transverse direction has a substantially oval shape having a major axis in the longitudinal direction and a minor axis in the transverse direction.
(12)
   The stacked structure according to any one of (1) to (11), in which
   the plurality of first bonding sections each has a first longitudinal direction and a first transverse direction,
   the plurality of second bonding sections each has a second longitudinal direction and a second transverse direction, and
   the plurality of first bonding sections and the plurality of second bonding sections are provided to cause the first longitudinal direction and the second longitudinal direction to intersect each other at a predetermined angle.
(13)
   The stacked structure according to (12), in which
   at least the first array has a rectangular shape,
   the first longitudinal directions of the plurality of first bonding sections and the second longitudinal directions of the plurality of second bonding sections periodically change from one side to another side of a pair of opposing sides of the first array, and
   the first longitudinal directions of the plurality of respective first bonding sections and the second longitudinal directions of the plurality of respective second bonding sections intersect each other at a substantially uniform angle, the plurality of respective first bonding sections and the plurality of respective second bonding sections intersecting each other.
(14)
   The stacked structure according to any one of (12) and (13), in which
   at least the first array has a rectangular shape, and
   the first longitudinal directions of the plurality of first bonding sections and the second longitudinal directions of the plurality of second bonding sections intersect each other at intersecting angles that periodically change from one side to another side of a pair of opposing sides of the first array.
(15)
   A semiconductor device including:
   a first substrate including a first surface and a second surface that are opposed to each other, the first substrate including a plurality of first semiconductor elements and a first array in which a plurality of first bonding sections provided at the second surface is provided in a row direction and a column direction in an array manner, the plurality of first bonding sections being correspondingly electrically coupled to the plurality of first semiconductor elements; and
   a second substrate including a third surface opposed to the second surface and a fourth surface disposed on an opposite side from the third surface, the second substrate including a plurality of drive circuits and a second array in which a plurality of second bonding sections provided at the third surface is provided in the row direction and the column direction in an array manner, the plurality of drive circuits controlling drive of the plurality of first semiconductor elements, the plurality of second bonding sections being correspondingly electrically coupled to the plurality of drive circuits, in which
   the plurality of first bonding sections, the plurality of second bonding sections, or both of the plurality of first bonding sections and the plurality of second bonding sections each have a plane shape having a longitudinal direction and a transverse direction that intersect each other, and
   of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.
(16)
   The semiconductor device according to (15), in which an array pitch for the plurality of first semiconductor elements is not more than 10 μm.
(17)
   The semiconductor device according to (15) or (16), in which the plurality of first semiconductor elements includes a light emitting element, a light receiving element, or a memory element.
(18)
   The semiconductor device according to any one of (15) to (17), in which the second substrate is larger than the first substrate.
(19)
   The semiconductor device according to any one of (15) to (18), further including a third substrate including a plurality of second semiconductor elements, in which the third substrate together with the first substrate is bonded to the second substrate.
(20)
   The semiconductor device according to any one of (15) to (19), further including a fourth substrate including a plurality of third semiconductor elements, the fourth substrate being stacked at a side of the first surface of the first substrate, in which
   the second substrate and the fourth substrate are electrically coupled through a through wiring.

The present application claims the benefit of Japanese Priority Patent Application JP2023-038822 filed with the Japan Patent Office on Mar. 13, 2023, the entire contents of which are incorporated herein by reference.

It should be understood that those skilled in the art could reach various modifications, combinations, sub-combinations and alterations on the basis of design requirements and other factors, and they are within the scope of the appended claims or the equivalents thereof.

1. A stacked structure comprising:
a first substrate including a first surface and a second surface that are opposed to each other, the first substrate including a first array in which a plurality of first bonding sections is provided at the second surface in a row direction and a column direction in an array manner; and
a second substrate including a third surface opposed to the second surface and a fourth surface disposed on an opposite side from the third surface, the second substrate including a second array in which a plurality of second bonding sections is provided at the third surface in the row direction and the column direction in an array manner, the plurality of second bonding sections being correspondingly bonded to the plurality of first bonding sections, wherein
the plurality of first bonding sections, the plurality of second bonding sections, or both of the plurality of first bonding sections and the plurality of second bonding sections each have a plane shape having a longitudinal direction and a transverse direction that intersect each other, and
of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.

2. The stacked structure according to claim 1, wherein the first substrate and the second substrate are bonded through hybrid bonding.

3. The stacked structure according to claim 1, wherein the first substrate and the second substrate have respective coefficients of linear expansion differing from each other.

4. The stacked structure according to claim 1, wherein the first substrate, the second substrate, or both of the first substrate and the second substrate comprise a semiconductor substrate.

5. The stacked structure according to claim 1, wherein the longitudinal direction of the plurality of bonding sections having the longitudinal direction and the transverse direction is parallel to or orthogonal to a linear expansion direction of each of the first substrate and the second substrate.

6. The stacked structure according to claim 1, wherein the plurality of bonding sections having the longitudinal direction and the transverse direction includes a straight region in at least a portion of the longitudinal direction and the transverse direction.

7. The stacked structure according to claim 1, wherein the plurality of bonding sections having the longitudinal direction and the transverse direction includes a curved region in at least a portion of the longitudinal direction and the transverse direction.

8. The stacked structure according to claim 1, wherein the plurality of bonding sections having the longitudinal direction and the transverse direction has a substantially rectangular shape having long sides and short sides.

9. The stacked structure according to claim 8, wherein the plurality of bonding sections having the longitudinal direction and the transverse direction includes a wide part at a portion of the long sides that are opposed to each other.

10. The stacked structure according to claim 9, wherein the wide part has a substantially round shape.

11. The stacked structure according to claim 1, wherein the plurality of bonding sections having the longitudinal direction and the transverse direction has a substantially oval shape having a major axis in the longitudinal direction and a minor axis in the transverse direction.

12. The stacked structure according to claim 1, wherein
the plurality of first bonding sections each has a first longitudinal direction and a first transverse direction,
the plurality of second bonding sections each has a second longitudinal direction and a second transverse direction, and
the plurality of first bonding sections and the plurality of second bonding sections are provided to cause the first longitudinal direction and the second longitudinal direction to intersect each other at a predetermined angle.

13. The stacked structure according to claim 12, wherein
at least the first array has a rectangular shape,
the first longitudinal directions of the plurality of first bonding sections and the second longitudinal directions of the plurality of second bonding sections periodically change from one side to another side of a pair of opposing sides of the first array, and
the first longitudinal directions of the plurality of respective first bonding sections and the second longitudinal directions of the plurality of respective second bonding sections intersect each other at a substantially uniform angle, the plurality of respective first bonding sections and the plurality of respective second bonding sections intersecting each other.

14. The stacked structure according to claim 12, wherein
at least the first array has a rectangular shape, and
the first longitudinal directions of the plurality of first bonding sections and the second longitudinal directions of the plurality of second bonding sections intersect each other at intersecting angles that periodically change from one side to another side of a pair of opposing sides of the first array.

15. A semiconductor device comprising:
a first substrate including a first surface and a second surface that are opposed to each other, the first substrate including a plurality of first semiconductor elements and a first array in which a plurality of first bonding sections provided at the second surface is provided in a row direction and a column direction in an array manner, the plurality of first bonding sections being correspondingly electrically coupled to the plurality of first semiconductor elements; and
a second substrate including a third surface opposed to the second surface and a fourth surface disposed on an opposite side from the third surface, the second substrate including a plurality of drive circuits and a second array in which a plurality of second bonding sections provided at the third surface is provided in the row direction and the column direction in an array manner, the plurality of drive circuits controlling drive of the plurality of first semiconductor elements, the plurality of second bonding sections being correspondingly electrically coupled to the plurality of drive circuits, wherein
the plurality of first bonding sections, the plurality of second bonding sections, or both of the plurality of first bonding sections and the plurality of second bonding sections each have a plane shape having a longitudinal direction and a transverse direction that intersect each other, and
of the plurality of bonding sections having the longitudinal direction and the transverse direction, a pair of the bonding sections disposed symmetrically with respect to a center of the array is substantially in mirror-image symmetry and each have the longitudinal direction forming an angle of an absolute value greater than 0 degrees and less than 90 degrees relative to the row direction or the column direction.

16. The semiconductor device according to claim 15, wherein an array pitch for the plurality of first semiconductor elements is not more than 10 μm.

17. The semiconductor device according to claim 15, wherein the plurality of first semiconductor elements comprises a light emitting element, a light receiving element, or a memory element.

18. The semiconductor device according to claim 15, wherein the second substrate is larger than the first substrate.

19. The semiconductor device according to claim 15, further comprising a third substrate including a plurality of second semiconductor elements, wherein
the third substrate together with the first substrate is bonded to the second substrate.

20. The semiconductor device according to claim 15, further comprising a fourth substrate including a plurality of third semiconductor elements, the fourth substrate being stacked at a side of the first surface of the first substrate, wherein
the second substrate and the fourth substrate are electrically coupled through a through wiring.
